(19) United States
(12) Patent Application Publication
(10) Pub. No.: US 2009/0085069 A1
(43) Pub. Date: Apr. 2, 2009

(54) NAND-type Flash Array with Reduced Inter-cell Coupling Resistance

(76) Inventors: Len MEI, San Jose, CA (US); Yue-Song HE, San Jose, CA (US)

Correspondence Address: MACPHERSON KWOK CHEN & HEID LLP, 2033 GATEWAY PLACE, SUITE 400, SAN JOSE, CA, 95110, US

(21) Appl. No.: 11/862,841

(22) Filed: Sep. 27, 2007

(51) Int. Cl. H01L 27/10; H01L 21/82

(52) U.S. Cl. 257/208; 438/129; 257/E27.07; 257/E21.602

(57) ABSTRACT

In a NAND-type nonvolatile reprogrammable memory array, inter-cell coupling resistance between adjoining memory cells is reducing by forming metal silicide insets embedded in the diffusion zone of the inter-cell coupling region. The diffusion zone includes a shallow implant region and a deep implant region. In one embodiment, the shallow implant region defines shallow source/drain regions for floating gate transistors of the memory cells. The size of the metal silicide insets are controlled to not compromise isolation PN junctions defined by the shallow and deep implant region. In one embodiment, the metal silicide insets include nickel.

### FIELD OF DISCLOSURE

The present disclosure of invention relates generally to nonvolatile reprogrammable memory devices having a NAND-type configuration (such as NAND-type Flash arrays) and more specifically to a method for reducing inter-cell coupling resistance within a string of NAND-coupled memory cells.

### DESCRIPTION OF RELATED TECHNOLOGY

NOR-type and NAND-type Flash memory arrays are two distinct kinds of well known memory arrays that contain nonvolatile reprogrammable memory cells.

Briefly, a NOR-type memory array comprises pairs of adjacent nonvolatile memory cells where each cell is constituted by, in one class of Flash-erasable devices, a floating gate transistor and where the adjacent cells share a common bit-line contacting region (i.e., a drain contact region) for making connection to a common bit-line. Sharing of the common bit-line contacting region helps to provide for a more compact layout than one where each cell has its own dedicated bit-line contacting region. In the NOR-type memory array, each member of the pair further shares a common current sourcing line with a respective next adjacent cell (i.e., a third FG transistor) so as to further provide for a compact layout. During a data reading operation, the common bit-line contacting region is charged to a predefined potential and one or the other, but not both of the contact sharing memory cells (i.e., FG transistors) is turned on for the purpose of sensing the amount of current flowing through it and into the bit line and for thereby determining the programmed or erased sate of the turned-on memory cell. The other memory cell that shares the common bit-line contacting region (i.e., the drain contact) is turned off during the reading operation and therefore its contribution to current flow in the common bit line is generally negligible (unless, of course, there is an undesirably large leakage of current by this purportedly turned off other cell due for example to over-erasure).

By contrast, in the NAND-type memory array a whole string of memory cells (a plurality of floating gate transistors in the case of one class of Flash memory arrays) are connected in series one to the next and all of them conduct a sensing current pulse during a data reading operation. The control gate of one cell in the series-connected string of memory cells is biased differently from those of all the rest so that the resistance of that one selected cell determines the strength of current pulse carried through the series connected string of cells.

NAND-type memory arrays have both advantages and disadvantages. On one hand, their cells can be packed more densely next to one another as compared to the cells of NOR-type arrays because the need for a common bit-line contacting region between successive pairs of cells is dispensed with in the NAND-type memory array. On the other hand, in the NAND-type memory array the speed of response to a data read request is generally much slower than that of a comparable NOR-type array because the state-determining current pulse that passes through the selected (addressed) one cell in the NAND series must also flow through the resistances of the other (non-addressed) cells in the series. As a result, the RC time delay constant for the state-determining current pulse tends to be substantially larger in a NAND-type memory array than that in a comparable NOR-type memory array. Artisans are therefore accustomed to the idea that the NAND-type memory array will inherently exhibit a relatively large series resistance in each of its respective strings of series connected memory cells and they are further accustomed to the idea that not much can be done about it.

By way of more specifics, in a typical NAND-type Flash memory array a long train of floating gate transistors (FG transistors) are connected together in series with each floating gate transistor comprising a source region, a drain region, a channel region (disposed between the source and drain of its FG transistor and also disposed above a substrate well), a tunnel insulator layer disposed over the channel region, a floating gate (FG) disposed over the tunnel insulator, a second insulator(s) layer (i.e. ONO stack) disposed over the FG, and a control gate (CG) disposed over the second insulator(s) layer. Flash memory arrays are generally erased as large blocks of many transistors that are cleared simultaneously rather than being erased one cell at a time (i.e., one bit at a time if data storage per cell is not of the multi-bit kind). During a block-wide erase, the source and drain of each transistor are typically disconnected from the power source (i.e. floated or tied to a very high impedance) while an appropriate erase voltage is applied across the control gate (CG) and a buried conductive band that extends in the substrate well (i.e., P-well) below each transistor. A common erase mode configuration might apply for example, approximately −9 Volts to the control gate and approximately +9V to the substrate well band so as to thereby induce tunneling (i.e. Fowler-Nordheim tunneling) of electrons from the floating gate (FG), through the tunnel insulator layer (i.e., tunnel oxide) and into the channel region or other parts of the substrate. Such positive charging of the floating gates (FG's) decreases a threshold voltage (Vₜ) above which the control gate (CG) must be later charged to in order to render the corresponding transistor conductive (e.g., turned ON) to a desired degree during selective read operations. The intent of a selective read operation is to pass a measurable drain-to-source current (I_{DS}) through the addressed transistor in response to the addressing-level turn on voltage, V_{Gon} applied to its control gate and the read-mode voltage, V_{Dread} applied to its drain by way of a bit line. If binary data storage is employed, then a relatively large I_{DS} will flow during reading and this will typically indicate the cell is still erased (i.e., to thereby represent a binary 1 bit for example). On the other hand, if a substantially smaller or no measurable I_{DS} current flows, this will typically indicate the addressed cell has been programmed (i.e., to thereby represent a binary 0 bit for example). If multi-bit data storage per cell is employed, then different ranges of I_{DS} will be allocated to respectively represent 00, 01, 10 and 11 for example.

Industry trends favor ever-shrinking sizes for transistors in both NOR-type and NAND-type Flash memory arrays so that more memory cells can be squeezed into a given space of an integrated memory chip. However, for the NAND-type memory array, down-scaling of transistor dimensions (e.g., reduction of source/drain junction depths and/or reduction of source/drain widths) can create unique problems that are not shared with the NOR-type design.

### SUMMARY

Structures and methods are provided in accordance with the present disclosure of invention for reducing inter-cell coupling resistance between memory cells of a NAND-type memory array.

In one embodiment, a silicide inset such as a nickel silicide inset is formed (embedded) inside the source/drain inter-cell coupling region (cell interconnect structure) between consecutive ones of NAND-connected floating gate transistors such that source and drain junction depths and/or junction structures near the channel regions are not substantially interfered with for each transistor and such that the formed silicide inset does not compromise the integrity of the source/drain PN junctions and/or alter the shapes, concentrations or other attributes of the source/drain PN junctions near the respective channel regions of the adjoining transistors to thereby substantially alter electric field distributions and thus perhaps cause increased junction leakage and/or other undesirable changes in transistor behavior. More specifically, in one embodiment, a relatively shallow first source/drain implant is provided across a first lateral distance (e.g., 70 nm long) spanning between two adjacent floating gate transistors. The width of this shallow source/drain implant is limited in the orthogonal lateral direction by surrounding trench isolation strips (e.g., a 70 nm bit-line-strip to bit-line-strip pitch filled with shallow trench isolation, STI). Masking sidewalls (spacers) are formed and a less long but deeper second source/drain implant is provided approximately midway within the first lateral distance as well as being bounded by the STI. With the added spacers still in place, a silicide-forming precursor metal (e.g., a nickel containing one) is deposited to make contact with the exposed silicon material where the second source/drain implant was provided. The combination is heated to initiate a silicidation reaction whose reaction front descends to a depth not exceeding the depth of the less long but deeper second source/drain implant. As a result, a low resistance inter-cell coupling region such as one having a nickel silicide inset is formed between each of the memory cells of a NAND-connected series of such cells. The formed inter-cell coupling region with the silicide inset embedded therein has a resistivity substantially less than the resistivity that the inter-cell coupling region would have without formation of the deeper second source/drain implant and formation of the silicide inset.

Other aspects of the disclosure will become apparent from the below detailed description.

### BRIEF DESCRIPTION OF THE DRAWINGS

The below detailed description section makes reference to the accompanying drawings, in which:

FIG. 1A is a schematic diagram of a series-connected plurality of memory cells forming a NAND memory row;

FIG. 1B is a cross sectional view for showing parts of two NAND memory rows sharing a common bit line and for further showing the start of a fabrication method in accordance with the disclosure;

FIG. 2 is a cross sectional view showing implant of a second deeper source/drain doping between each of the memory cells of the structure of FIG. 1B after spacer sidewalls have been formed;

FIG. 3 is a cross sectional view showing deposition of the precursor metal prior to initiation of the silicidation reaction; and

FIG. 4 is a cross sectional view showing the resultant structure after silicidation and selective removal of left over portions of the precursor metal.

### DETAILED DESCRIPTION

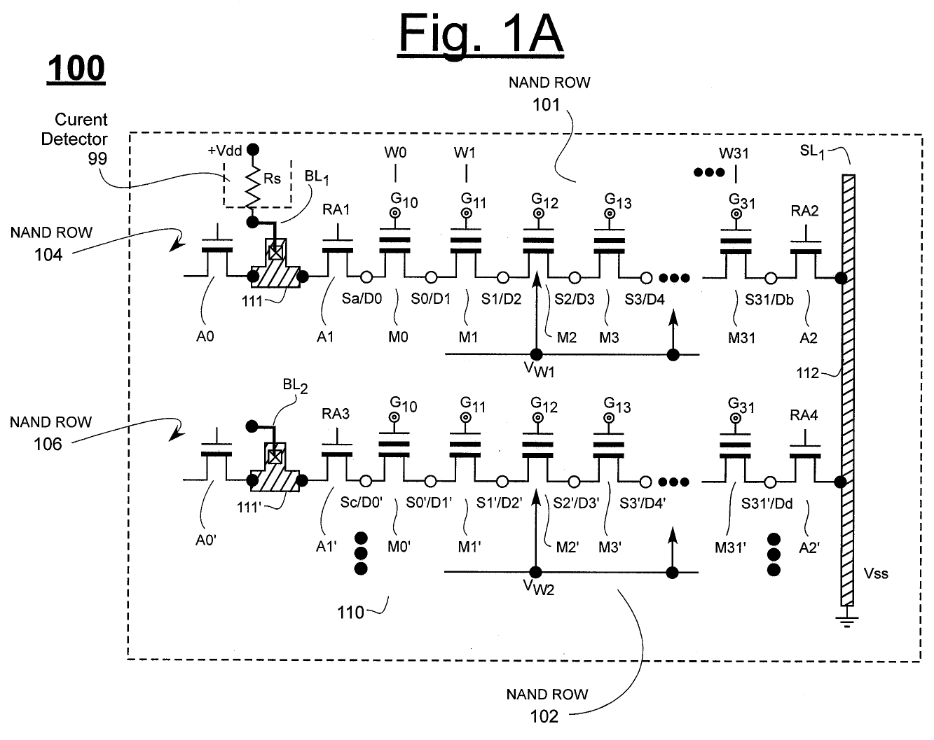

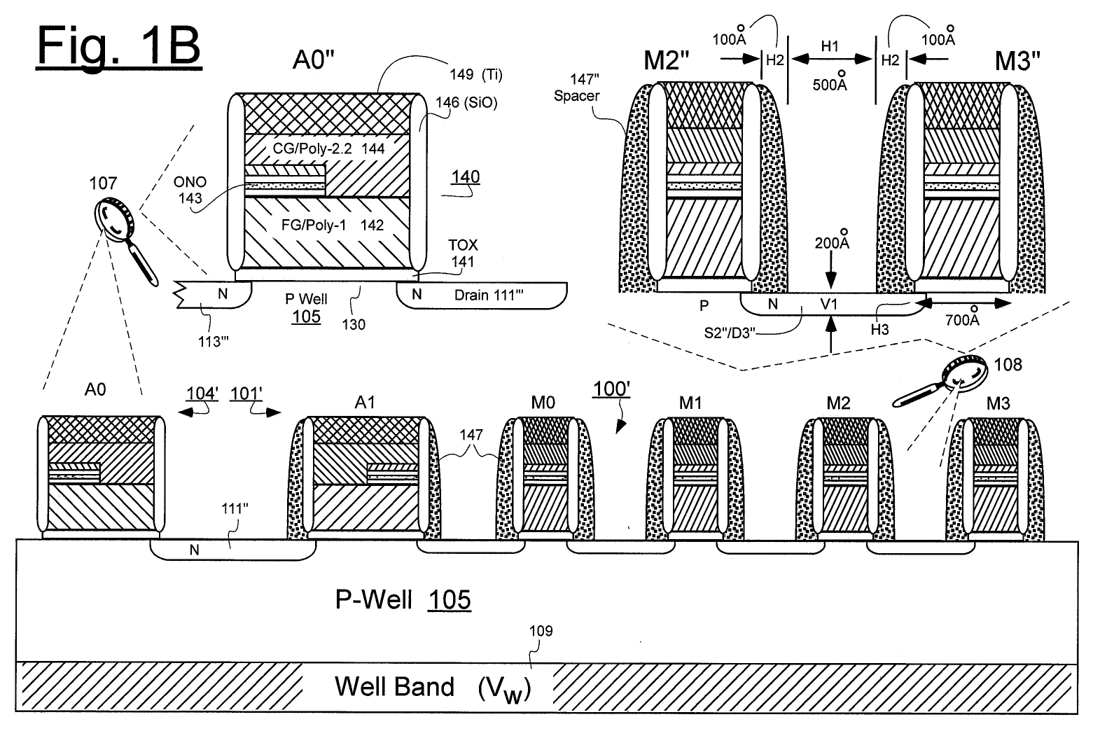

FIG. 1A provides a circuit schematic view of a monolithic integrated circuit 100 that includes a NAND-type memory array 110. The array 100 comprises a first NAND row 101 and a second NAND row 102 each containing a series connected plurality of thirty two floating gate (FG) transistors (memory cells M0-M31) and two row-addressing/decoupling transistors (A1, A2) provided in series at opposed ends of the corresponding NAND row. Of course it is within the contemplation of the present disclosure to have other numbers of memory cells connect in electrical series in each NAND row such as 16 cells per row or 48 or 64 cells per row for example.

Layout compaction is achieved due to the sharing of the source/drain diffusion regions (e.g., S0/D1) between pairs of immediately adjacent memory cells (e.g., M0 and M1) in each NAND row. A first conductive diffusion line 111 intersects with the drain side of NAND row 101 for connecting that row (and another partially-shown NAND row 104 on the other side of 111) with a first metal bit line (BL1) that further connects to a current detector 99. For sake of simplicity, the current detector 99 is represented as including a current sensing resistor (Rs) whose other end is connected to a drain-side voltage supply (+Vdd). Other current detector designs can be used instead, including for example capacitive discharge kinds where Vdd is charged across a capacitor and then the capacitor is discharged through the selected NAND row during a predefined sensing period.

As seen in FIG. 1A, a second conductive diffusion line 111′ joins with the drain side of second NAND row 102 for connecting it (and another partially-shown NAND row 106) with a second metal bit line (BL2). It is understood that BL2 couples to a respective current detector (not shown) similar to detector 99. The bit line contact diffusions, 111, 111′, etc., may be comprised of N+ doped diffusions implanted in the silicon substrate of the IC 100. An overlying metal line is often provided to define the corresponding bit line (BL1, BL2, etc.) and to make ohmic contact with its respective bit line contact diffusions, 111, 111′, etc. and with circuitry of the corresponding current detectors (e.g., 99).

A further conductive diffusion line 112 (common source diffusion) crosses with the source side of NAND rows 101, 102, etc., for connecting the rows with a source-side voltage supply (Vss). The common source diffusion 112 may be comprised of an N+ doped diffusion in the silicon substrate of the IC 100. An overlying metal line (not shown) may be provided to make periodic ohmic contact to the common source diffusion 112 and thereby reduce source resistance coupling to the Vss node (e.g., ground). Word lines (not fully shown) further cross through the array 110 to connect to respective gates G10, G11, . . . G31 of the memory cell transistors. For example, one word line, W0 connects the G10 gate terminals of all NAND rows 101, 102, etc. in the array 110 to a first word line driver circuit (not shown). A second word line, W1 connects the G11 gate terminals of all rows 101, 102, etc. in the array 110 to a second word line driver circuit (not shown) and so forth. The word lines may be comprised of patterned portions of a second polysilicon layer (not shown, see instead 144 and 149 of FIG. 1B).

During a bit reading operation of say, one memory cell in the first row 101, the corresponding row-addressing/row decoupling transistors A1 and A2 are turned on (driven to be conductive) by their respective gate drive signals, RA1 and RA2, while all remaining rows of conductive bit line contact 111 are blocked from conducting series currents by turning off one or both of their row-addressing transistors (e.g., A0, A1′ and A2′) by applying deactivating voltages (i.e., 0V) on their respective gate drive lines (e.g., RA3 and RA4). Then within the selectively addressed one row (e.g., 101), all word lines (W0-W31) except for the one connected to the addressed cell are driven to high bias levels (well above threshold) that force their respective memory cells (M0-M31) into low resistance modes irrespective of the programmed or erased states of those high-biased memory cells. The one memory cell (e.g., M2) that is being addressed has its gate (i.e., G12) driven to a lower bias voltage (e.g., slightly below the nominal programmed threshold level of the floating gate transistors, for example to about 0V) such that the resistance of the corresponding NAND row 101 is substantially determined by the programmed or erased state of that one addressed memory cell (e.g., M2). The magnitude of current flow through the current detector 99 (e.g., through sense resistor Rs) of the corresponding bit line (BL1) is therefore determined by the programmed or erased state of that one addressed memory cell (e.g., M2). The detector 99 includes a circuit (not shown) for determining the amount of current passed through the addressed NAND row (e.g., 101) during the read cycle and for thereby determining the state of the addressed memory cell (e.g., M2). Selective programming can be achieved with a different mechanism involving conductive well bands and application of well voltages Vw1, Vw2 to the P-well bands of the different rows. The row-addressing/row decoupling transistors (e.g., A1 and A2) are both turned off (driven to be nonconductive) by their respective gate drive signals (e.g., RA1 and RA2) during a row erase operation.

One assumption that is made during the course of a memory read operation is that there are no relatively high resistance elements in the series circuit of the addressed NAND row (e.g., 101) except for possibly the resistance of the one selected memory cell (e.g., M2) if it is in a programmed rather than erased state. In this case, the magnitude of resistance that is deemed to constitute a high resistance depends on the RC time constants called for by the design of the current detector 99. In general there will be a predefined limit on how large a resistance is acceptable for an addressed NAND row during a data read cycle. If the effective resistance of an addressed NAND row is too large during a data read cycle, then not enough current will flow to the detector 99 and the detector 99 might not be able to reliably discern between a programmed versus erased state of the addressed memory cell (e.g., M2) relative to background noise.

In light of this, a problem develops if the shared source/drain diffusions (i.e., Sa/D0, S0/D1, S1/D2, . . . , S30/D31, S31/Db) of each NAND row begin to operate as significant resistors in their own rights rather than acting as highly conductive intercouplings between the respective memory cells of the given NAND row (e.g., 101). In the case where there are about 32 or more such shared source/drain diffusions along the series circuit of a given NAND row, even small increases in effective resistance of the shared source/drain diffusions can be multiplied by a factor of about 32 or more so as to produce a combined resistance that challenges the maximum series resistance allowed by design for the NAND row during a read cycle. Designers of memory circuits want to have a good margin of error for noise so that the memory circuit can function reliably even in a moderately noisy environment. However, if the resistance of the inter-cell couplings between the respective memory cells grows too large, this may not be possible.

FIG. 1B is a cross sectional view for showing parts of two NAND memory rows (101′ and 104′) that share a common bit line contact region 111″ and are formed as a line over a common P-well 105 and a corresponding, P+ doped well band 109 of IC device 100′. Although not explicitly shown in FIG. 1B, it is to be understood that the substrate strip (including well band 109) that supports the represented strip of NAND-connected memory cells and row select transistors (e.g., M0-M3, . . . , M31; A1, A2) is embraced on its sides (moving fore and aft in the direction orthogonal to the drawing sheet) by shallow trench isolation (STI, which in one embodiment is composed of silicon oxide and has a width of about 70 nm and a depth of about 200 nm).

A first magnified view 107 (not to scale) is provided in FIG. 1B to show details of row selecting/decoupling transistor A0. A left half of transistor A0 has a structure substantially similar to those of memory cells M0, M1, M2, etc. and therefore a completely separate description of the memory cell structures will not be provided herein.

The magnified version A0″ of row selecting/decoupling transistor A0 is shown to comprise a gate stack 140 which in one embodiment has an upper metallization and/or silicidation 149 already formed on top of an upper polysilicon layer 144. In an alternate embodiment, the upper metallization and/or silicidation 149 (e.g., Ti and/or SiTi) is not present and tops of oxide sidewalls 146 (detailed below) terminate instead at the top surface of the upper polysilicon 2.2 layer (part of 144). The gate stack 140 defines part of an insulated gate field effect transistor that further includes an N-type drain region 111′″, an N-type source region 113′″, and a P-type channel region 130 interposed laterally between the drain 111′″ and source 113′″. The source and drain regions, 111′″ and 113′″, are defined by N-type dopants implanted in a P-well 105 that is contiguous with the channel region 130. The source, drain, channel and well regions may be integrally formed as part of a monolithic semiconductor substrate (i.e., monocrystalline silicon) by way of various well known doping techniques such as ion implant. It is to be understood that drain region 111′″ corresponds to the N-type bit line 111″ of IC device 100′ in FIG. 1B and to the bit line 111 of device 100 in FIG. 1A.

The illustrated gate stack 140 includes a tunnel oxide region 141 that separates a conductive floating gate 142 (i.e., first polysilicon layer) from the channel region 130 by a sufficiently small distance so as to enable electron tunneling through the lower gate insulator 141. A thicker dielectric region 143 (typically of an Oxide/Nitride/Oxide configuration, or ONO) separates the floating gate 142 from a conductive control gate 144 (i.e., polysilicon 2.2 layer). The illustrated embodiments include a conductive polysilicon 2.1 layer shown to be disposed on top of the 3 layer ONO stack. In the memory cells M0-M31, the thicker dielectric region 143 (e.g., ONO) fully isolates the control gate 144 and the interfacing polysilicon 2.1 layer from the floating gate 142. However, in the illustrated row selecting/decoupling transistor A0″, the poly-2.2 layer is deposited to wrap around the ONO stack 143 and to thus short to the lower poly-1 layer and thereby cause device A0″ to function as a single gate MOSFET rather than as a floating gate transistor. Although not fully shown, it is to be understood that the control gates (CG) 144 of memory cells M0-M31 are in communication with respective word lines (WL's) that extend orthogonally relative to the plane of the paper and that generally receive cell-addressing signals for determining whether that particular cell (e.g., M2) is to be read, not read, programmed, or not programmed.

In the memory cells (M0-M31), first sidewall dielectric regions 146 join at their bottoms with the TOX 141 to fully isolate the floating gate layer 142 and thereby provide isolation for gate structure 140 so that charge can be efficiently trapped in its floating gate (FG) 142. Dopants for the source and drain regions, 113′″-111 are typically implanted after the first sidewalls 146 are defined so that the source and drain regions, 113′″-111′″ are self-aligned relative to the outer surfaces of the first sidewalls 146. Metallization/silicidation layer 149 is typically not present at the time of the self-aligned implant of the source and drain regions, 113′″-111, and thus the source/drain implant also contributes to doping of the upper polysilicon layer 144. As seen in FIG. 1B in the adjacent magnification 108 of memory cells M2 and M3, the source region S2″ of cell M2 is defined by a common implant S2″/D3″ that also defines the self-aligned drain region D3″ of memory cell M3 and no provision is made in that space for a drain contact. This allows for a compact cell-to-cell packing layout that is typically associated with the NAND-type memory array configuration.

As the dimensions of memory cells like M2 and M3 are scaled to smaller and smaller values, the implant and post-diffusion depths (vertical dimension V1) of their respective source/drain regions (e.g., S2″/D3″) have to be scaled to correspondingly smaller values so as to prevent punch through of the respectively formed transistors. In one particular design, a 70 nm/70 nm pitch is proposed where a first horizontal spacing dimension (H₁+2*H₂) between outwardly facing first sidewalls (146) of adjacent memory cells (e.g., M2″ and M3″) is about 70 nanometers (700 Angstroms) and where a second horizontal spacing dimension (H₃) between the first sidewalls (146) of a given memory cell (e.g., M3″) is also about 70 nanometers.

The proposed design depth for the respective source/drain regions (e.g., S2″/D3″) is about 20 nanometers (200 Angstroms) in such a case. If the respective source/drain regions were to be formed to greater depths there would be substantial danger of punch through across the 70 nanometer or narrower channels of the transistors.

Accordingly, the shallow source/drain depth (vertical dimension V1) is highly desirable if not necessary for preventing punch through and/or excessive leakage during transistor operation. It is to be understood that the exemplary dimension of V1 for the shallow implant being about 200 Angstroms is only an example and that in other designs V1 could be substantially smaller while in yet other designs it might be substantially larger. Also during scale down, the widths (W) of the source/drain regions are usually reduced. Irrespective of the specific dimensions, when scaling occurs to small dimensions such as junction depths of about 200 Angstroms or smaller, the electrical resistances of the shallow depth and usually-narrowed inter-cell coupling source/drain regions (e.g., S2″/D3″) can become undesirably large due to the fact that resistance is a function of diffusion length, diffusion width, diffusion depth (L×W×V) and dopant concentration or resistivity per cubic unit. Since the proposed depths (V1) for the respective source/drain regions (e.g., S2″/D3″) is about 20 nanometers in the instant case and could be even smaller as geometries scale to yet smaller values, resistance of the inter-cell coupling regions (e.g., S2″/D3″) becomes a growing problem. If the cumulative resistances of the N+1 inter-cell coupling regions in a NAND row having N memory cells becomes too large (where N=16, 32, 48, 64 for example), it can prevent a row sensing pulse of sufficient current magnitude from flowing through the NAND row.

In one particular design situation where V1 is about 200 Å, the resistivity of each shallow depth inter-cell coupling region (junction) is about 5K ohms per square thus creating a combined resistance of 33 times the per junction resistance for 33 such inter-cell coupling junctions. The combined resistance can become sufficiently large to constitute a problem when considered in conjunction with noise immunity attributes desired for the device. (In one embodiment, each NAND row is required to conduct a sensing current of at least 1 microamp during the read cycle even when all 32 memory cells of the NAND string are programmed. For such a specific case the 5K ohms per square resistivity value plus settings for Vdd and Vss make reliable attainment of that minimum current flow requirement questionable in light of mass production variabilities.)

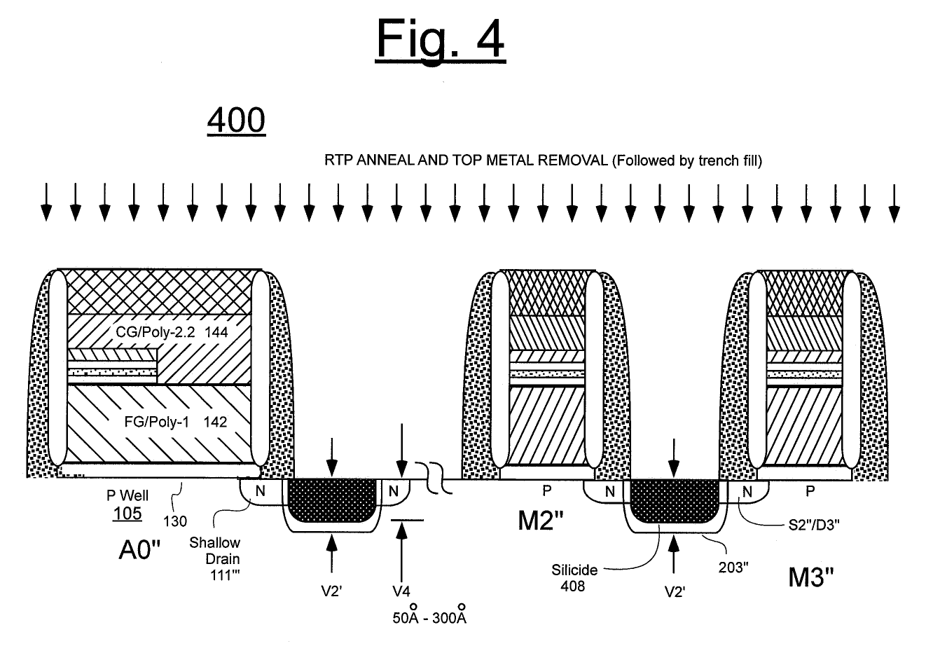

In accordance with one aspect of the present disclosure, after the first sidewalls 146 are defined and a first shallow implant is performed for self-aligning the source/drain regions (e.g., S2″/D3″) to the first sidewalls 146, a supplemental set of dielectric sidewalls 147 (spacers) are formed. The supplemental dielectric sidewalls 147 may be formed with any appropriate sidewall forming technique; HTO for example (High Temperature Oxidation). The thickness (H2) of each supplemental dielectric sidewall 147 is substantially less than half the first sidewall to first sidewall pitch dimension (H2<(H₁+2*H₂)/2) so as to leave a sufficient spacing H1 between the second sidewalls 147″ of adjacent memory cells (M2″, M3″) for depositing a film of precursor metal therebetween where the precursor metal is to be later consumed for forming a silicide (e.g., nickel silicide). In one embodiment, horizontal dimension H1 is about 500 Å and second horizontal dimension H2 is about 100 Å. In a later step (see FIG. 4), a precursor metal (e.g., nickel) will be conformably deposited or filled into the H1 wide horizontal space. It is to be noted again that in one alternate embodiment, the Ti/SiTi caps 149 are not present and therefore the top surfaces of the silicon control gate layers 144 are instead exposed.

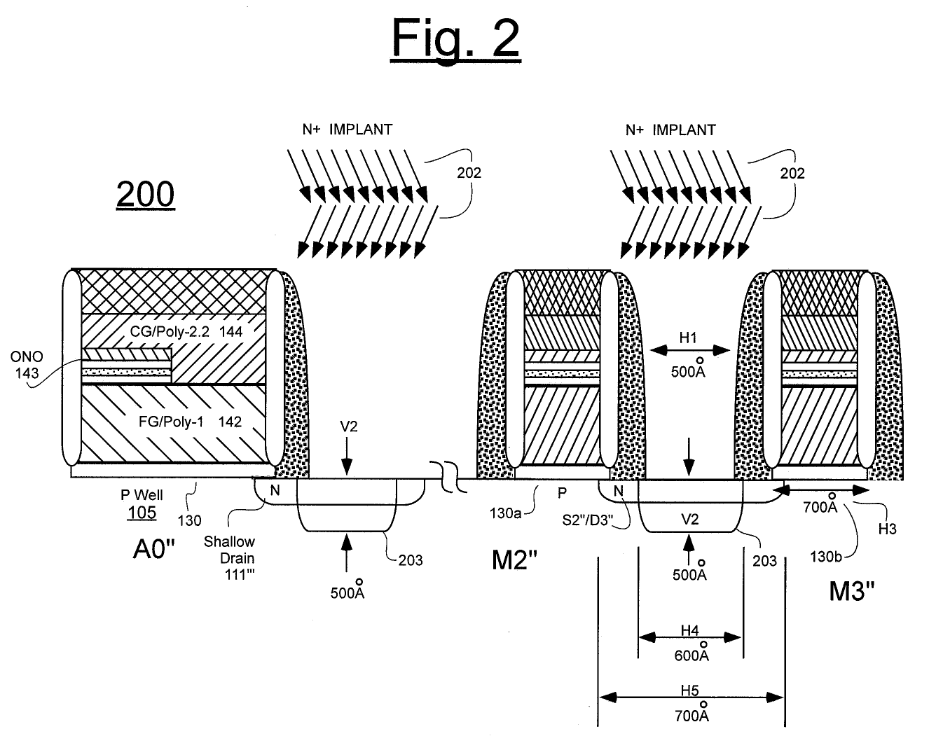

Referring to FIG. 2, following formation of the supplemental set of dielectric sidewalls 147 (spacers), an untilted or tilted angle ion implant of source/drain dopants (e.g., N+) is performed to a second vertical implant depth V2 which is substantially greater than the first vertical dimension V1 of the shallow source/drain regions (e.g., S2″/D3″) of FIG. 1B. In one embodiment, the second vertical implant depth V2 is about 500 Å. The angles (e.g., about 7° or less) of the tilted angle implant 202 are selected to avoid undesirable channeling. Ion scattering causes the V2 deep implants 203 to attain a lateral dispersion H4 that is greater than the horizontal spacing H1 between the supplemental dielectric sidewalls 147 (spacers) but less than the lateral spacing H5 between the corresponding channel regions, 130a and 130b. In one embodiment, H1 is about 500 Å, H4 is about 600 Å, and H5 is about 700 Å. These numbers could be scaled to smaller dimensions or slightly larger ones depending on specific applications.

In an alternate embodiment (not shown), the deep implant 202 is carried out as a vertical rather than tilted angle implant and thereafter additional sidewall spacers (not shown) are formed on spacers 147 so that the lateral ends of the V2-deep implants 203 are overlapped by the sidewall spacers as shown in FIG. 2.

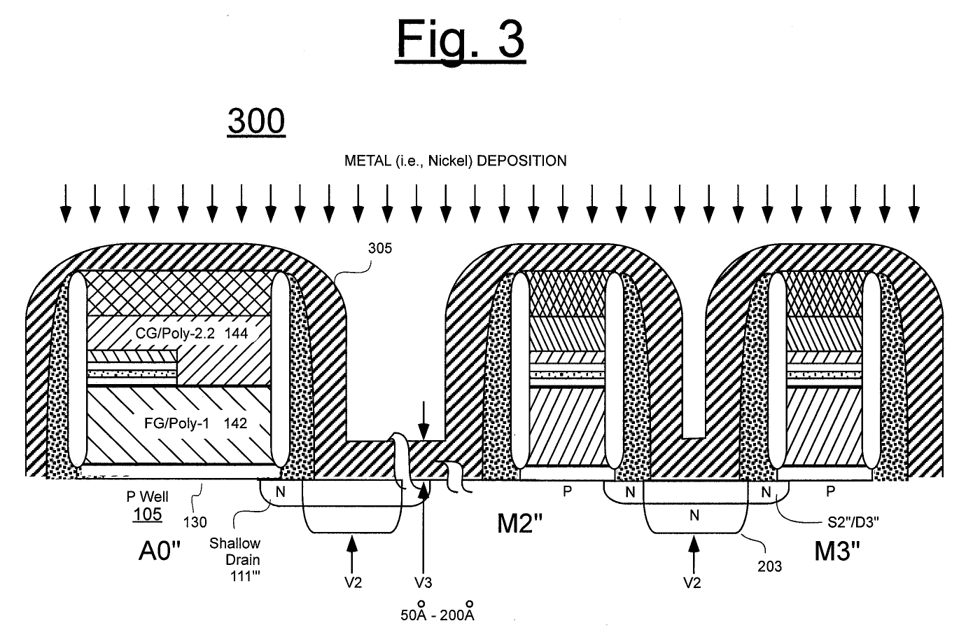

Referring to FIG. 3, following formation of the spacer under-cutting deep implants 203, a precursor metal 305 is deposited on the in-process structure 200 of FIG. 2. The precursor metal 305 may include any suitable metals for forming low-resistivity silicides with the silicon material of deep implant regions 203′ such as cobalt, nickel or titanium. In one particular embodiment, the deposited precursor metal 305 essentially consists of, or is predominantly composed (e.g., by weight or stoichiometrically) of nickel. Formation of nickel silicide tends to be a slow and therefore more precisely controllable reaction than formation of other such metal silicides, and therefore; given the relatively small depth V2 (e.g., 500 Å) of the under-cutting deep implants 203′ it is advantageous to employ a precursor material 305 whose reaction rate and reaction uniformity can be well controlled.

A variety of specific techniques may be used for formation of the precursor metal layer 305 on top of the structure 200 formed in FIG. 2. By way of nonlimiting examples, the metal precursor layer 305 may be deposited by atomic layer deposition (ALD) methods, by physical vapor deposition (PVD) methods, by chemical vapor deposition (CVD) methods and/or by sputtering and the precursor metal layer 305 may essentially consist of any one or more of, or its composition may be predominated by any one or more of nickel (Ni), titanium (Ti), tungsten (W) and cobalt (Co). Examples of specific methods that may be used include those disclosed in US Patent Publication 2005/0176227 by Chii-Ming Wu et al. (Method of Forming Metal Silicide, published Aug. 11, 2005) and in US Patent Publication 2007/0178696 by Chii-Ming Wu et al. (Method for Silicide Formation on Semiconductor Devices, published Aug. 2, 2007) whose disclosures are incorporated herein by reference. In one embodiment, the precursor metal layer 305 has a thickness V3 of about 50 Å to 200 Å and it is conformably coated over the structure 200 of FIG. 2. The specific thickness and/or conformal coating are not essential. The main point is to provide a uniform supply of precursor metal in the H1 wide spaces of FIG. 2 and able to flow into contact or to be in contact with the top surfaces of the deep implants 203 so that a controllable uniform silicidation process may next take place as indicated in FIG. 4.

Referring to FIG. 4, the deposited precursor metal layer 305 of FIG. 3 is subjected to an annealing temperature (e.g., about 500° C.˜850° C.) for an appropriate length of time (e.g., about 30 seconds to about 90 seconds) so as to cause silicidation of the silicon material in the V2 deep implants 203 to a depth V4 less than V2. In one embodiment, where V2 is 500 Å, the controlled silicidation depth V4 is in the range of about 50 Å to 300 Å. The anneal process may include use Rapid Thermal Anneal (RTP) heat lamps. In the case where the upper metallization and/or silicidation 149 (e.g., Ti and/or SiTi) is not present in FIG. 1B and the top surface of the upper polysilicon 2.2 layer (part of 144) was instead exposed, the anneal of FIG. 4 can also cause silicidation of the exposed tops of the upper polysilicon 144 if it too is conformably covered by the precursor metal layer 305. In one embodiment, the precursor metal layer 305 is mostly comprised of or consists of nickel. Reaction of silicon with nickel is relatively slow and thus the depth of silicidation can be accurately controlled. The precursor metal layer 305 does form silicide with the adjoining STI isolation strips (not shown) that surround the P-well 105 (see FIG. 1B) and thus interference with isolation in the lateral direction orthogonal to the drawing sheet is not a concern.

It is important that the silicidation front of the growing silicide inset 408 (FIG. 4) not cross into the depletion zone of the PN junction defined by deep implant 203″ so as to thereby compromise the reverse junction isolation between the P-well 105 and the combination of source/drain diffusion region S2″/D3″ and deep implant 203″. At the same time, it is desirable to form the silicide inset 408 (e.g., nickel silicide) to a depth and width sufficient for substantially reducing the resistance of the inter-cell coupling regions (e.g., source/drain S2″/D3″). In one embodiment, it is projected by simulation that the total resistance of a 32 memory cell NAND row can be reduced by more than half with use of the nickel silicidation process with silicide growth depth of about 200 Å, provided the nickel silicide inset 408 provides a resistivity of no more than about 10 ohms per square as compared to the substantially higher (more than about one order of magnitude higher, or more specifically about 100 times higher or yet higher) resistivity of about 5K ohms per square or more of the shallow source/drain implant. As a result, the NAND row can pass a read pulse of more than double the magnitude under same Vdd, Vss and Vg conditions (e.g., Vdd=+1 volt, Vss=0V and Vg=4.5V) and the tolerance for background noise of the memory system is thereby significantly enhanced.

Still referring to FIG. 4, after the silicidation process completes to the desired depth V4 (e.g., 200 Å), remaining parts of the precursor metal layer 305 can be removed with a wet acidic etch to thereby leave behind the illustrated structure.

In a next step (not shown), trenches between the illustrated memory cells (e.g., M2″, M3″) of FIG. 4 are filled with an appropriate dielectric where the latter may include a low-K dielectric for keeping capacitive crosstalk coupling between adjacent memory cells small.

The present disclosure is to be taken as illustrative rather than as limiting the scope, nature, or spirit of the subject matter claimed below. Numerous modifications and variations will become apparent to those skilled in the art after studying the disclosure, including use of equivalent functional and/or structural substitutes for elements described herein, use of equivalent functional couplings for couplings described herein, and/or use of equivalent functional steps for steps described herein. Such insubstantial variations are to be considered within the scope of what is contemplated here. Moreover, if plural examples are given for specific means, or steps, and extrapolation between and/or beyond such given examples is obvious in view of the present disclosure, then the disclosure is to be deemed as effectively disclosing and thus covering at least such extrapolations.

### Reservation of Extra-Patent Rights, Resolution of Conflicts, and Interpretation of Terms

After this disclosure is lawfully published, the owner of the present patent application has no objection to the reproduction by others of textual and graphic materials contained herein provided such reproduction is for the limited purpose of understanding the present disclosure of invention and of thereby promoting the useful arts and sciences. The owner does not however disclaim any other rights that may be lawfully associated with the disclosed materials, including but not limited to, copyrights in any computer program listings or art works or other works provided herein, and to trademark or trade dress rights that may be associated with coined terms or art works provided herein and to other otherwise-protectable subject matter included herein or otherwise derivable herefrom.

If any disclosures are incorporated herein by reference and such incorporated disclosures conflict in part or whole with the present disclosure, then to the extent of conflict, and/or broader disclosure, and/or broader definition of terms, the present disclosure controls. If such incorporated disclosures conflict in part or whole with one another, then to the extent of conflict, the later-dated disclosure controls.

Unless expressly stated otherwise herein, ordinary terms have their corresponding ordinary meanings within the respective contexts of their presentations, and ordinary terms of art have their corresponding regular meanings within the relevant technical arts and within the respective contexts of their presentations herein. Descriptions above regarding related technologies are not admissions that the technologies or possible relations between them were appreciated by artisans of ordinary skill in the areas of endeavor to which the present disclosure most closely pertains.

Given the above disclosure of general concepts and specific embodiments, the scope of protection sought is to be defined by the claims appended hereto. The issued claims are not to be taken as limiting Applicant's right to claim disclosed, but not yet literally claimed subject matter by way of one or more further applications including those filed pursuant to 35 U.S.C. §120 and/or 35 U.S.C. §251.

What is claimed is:

1. A NAND-type memory array comprising:
a plurality of NAND rows integrally formed in a silicon-containing semiconductor substrate, where each of the NAND rows includes a plurality of serially interconnected memory cells that are connected one to the next by adjoining memory cell interconnect structures, and
where the memory cell interconnect structures each includes a respective metal silicide inset embedded therein.

2. The NAND-type memory array of claim 1 wherein:
each memory cell includes at least a first transistor having a source region, a drain region, a channel region laterally interposed between the source and drain region and a first gate disposed above the channel region; and
the memory cell interconnect structures each includes a shallow implant region implanted into the substrate to a first depth and merging contiguously with the source or drain region of the first transistor of an adjoining memory cell and a deep implant region implanted into the substrate to a second depth that is substantially greater than the first depth; and
said metal silicide inset of each memory cell interconnect structure is embedded in the deep implant region to a third depth that is less than the second depth.

3. The NAND-type memory array of claim 2 wherein:
the first depth is about 200 Angstroms or less; and
the second depth is about 400 Angstroms or more.

4. The NAND-type memory array of claim 2 wherein:
the third depth is in the range of about 50 Angstroms to 300 Angstroms.

5. The NAND-type memory array of claim 4 wherein:
the metal silicide inset includes nickel.

6. The NAND-type memory array of claim 1 wherein:
the metal silicide inset includes nickel.

7. The NAND-type memory array of claim 2 wherein:
channel regions of adjoining memory cells are laterally spaced apart from one another by at least a first lateral spacing dimension;
the deep implant regions each has a lateral width that is substantially less than the first lateral spacing dimension.

8. The NAND-type memory array of claim 7 wherein:
the first lateral spacing dimension is about 700 Angstroms or less; and
the lateral width of each deep implant region is about 600 Angstroms or less.

9. The NAND-type memory array of claim 7 wherein:
each metal silicide inset has a second lateral width that is substantially less than the lateral width of its respective deep implant region.

10. The NAND-type memory array of claim 9 wherein:
the second lateral width is about 500 Angstroms or less.

11. A method of fabricating a NAND-type memory array integrally on a silicon-containing semiconductor substrate, the method comprising:
(a) forming spaced apart memory cell stack structures on the substrate where each memory cell stack structure comprises a tunneling dielectric layer, a first gate layer, a second gate layer, an inter-gate insulator interposed between the first and second gate layers, and a first sidewall insulator surrounding the first and second gate layers and the inter-gate insulator;
(b) implanting source/drain dopants between the formed memory cell stack structures to thereby provide shallow source/drain regions of a first depth below a top major surface of the substrate;
(c) after the implanting of the source/drain dopants, forming on each memory cell stack structure a second sidewall insulator surrounding the first sidewall insulator;
(d) after forming the second sidewall insulators, implanting further source/drain dopants between the memory cell stack structures to thereby provide deep source/drain implant regions of a second depth that is greater than said first depth;
(e) after implanting the further source/drain dopants, depositing a precursor metal between the memory cell stack structures to make contact with the deep source/drain implant regions; and
(f) reacting the precursor metal with the contacted deep source/drain implant regions.

12. The method of claim 11 wherein:
(a.1) the first gate layer has a length of about 70 nm or less.

13. The method of claim 11 wherein:
(b.1) the first depth is about 200 Angstroms or less.

14. The method of claim 11 wherein:
(c.1) the second sidewall insulator has a thickness that is less than half of a spacing present between facing outer parts of the first sidewall insulator of adjoining memory cell stack structures.

15. The method of claim 14 wherein:
(c.1a) the thickness of the second sidewall insulator is about 100 Angstroms or less.

16. The method of claim 11 wherein:
(d.1) the second depth is about 500 Angstroms or less.

17. The method of claim 11 wherein:
(e.1) said depositing of the precursor metal layer includes forming a layer of precursor metal having a thickness of about 200 Angstroms or less.

18. The method of claim 11 wherein:
(e.1) said precursor metal consists essentially of nickel.

19. The method of claim 11 wherein:
(e.1) said precursor metal is predominantly composed by weight of nickel.

20. The method of claim 11 wherein:
(e.1) said precursor metal includes one or more metallic elements that react with silicon to form silicides having sheet resistances of about one fifth or less of a sheet resistance of the shallow source/drain regions.

21. The method of claim 11 wherein:
(f.1) said reacting includes performing a high temperature anneal.

22. The method of claim 11 wherein:
(f.1) said reacting of the precursor metal is carried out to create a silicide inset having a depth that is less than the second depth of the deep source/drain implant regions.

23. The method of claim 11 wherein:
(d.1) said implanting of the further source/drain dopants includes performing a tilted angle ion implant.

24. The method of claim 11 and further comprising:
(g) after said reacting of the precursor metal, removing left over, unreacted portions of the precursor metal.
